(19) United States
(12) Patent Application Publication
(10) Pub. No.: US 2026/0074143 A1
(43) Pub. Date: Mar. 12, 2026

(54) COLUMN, PROCESSING ARRANGEMENT AND METHOD

(71) Applicant: Carl Zeiss SMT GmbH, Oberkochen (DE)

(72) Inventors: Katharina Gries, Darmstadt (DE); David Laemmle, Darmstadt (DE); Marion Batz, Wiesbaden (DE); Daniel Alexander Emmrich, Darmstadt (DE); Jan-Hannes Plote, Suwon-si (KR); Lutz Ackermann, Dresden (DE); Gunther Scheunert, Brombachtal (DE); Martin Reuss, Dieburg (DE)

(21) Appl. No.: 19/395,469

(22) Filed: Nov. 20, 2025

Related U.S. Application Data
(63) Continuation of application No. PCT/EP2024/064017, filed on May 22, 2024.

(30) Foreign Application Priority Data
May 22, 2023 (DE) 102023113302.0

(51) Int. Cl. H01J 37/244; H01J 37/147; H01J 37/18; H01J 37/20; H01J 37/28

(52) U.S. Cl. CPC H01J 37/244; H01J 37/147; H01J 37/18; H01J 37/20; H01J 37/28; H01J 2237/24475

(57) ABSTRACT

A column for analyzing and/or processing a sample, for example a mask for a lithography apparatus, comprising a particle source configured to emit a particle beam in a first direction onto the sample, a detector device configured to detect particles moving in a second direction opposite to the first direction, and a positioning device configured to position the detector device in a plane oriented perpendicular to the first direction.

### CROSS-REFERENCE TO RELATED APPLICATIONS

This application is a continuation of and claims benefit under 35 U.S.C. § 120 from PCT application PCT/EP2024/064017, filed on May 22, 2024, which claims priority from German patent application 10 2023 113 302.0, filed on May 22, 2023. The entire contents of each of these earlier applications are incorporated herein by reference.

### TECHNICAL FIELD

The present invention relates to a column, a processing arrangement and a method.

### BACKGROUND

Microlithography is used to produce microstructured components, for example integrated circuits. The microlithography process is carried out using a lithography apparatus comprising an illumination system and a projection system. The image of a mask (also referred to as reticle or lithography mask) illuminated by use of the illumination system is projected here by use of the projection system onto a substrate, for example a silicon wafer, which is coated with a light-sensitive layer (photoresist) and arranged in the image plane of the projection system, in order to transfer the mask structure to the light-sensitive coating of the substrate.

The mask is used for a multitude of exposures. It is thus important that it is free of defects. Great efforts are correspondingly made to examine the mask for defects and to repair recognized defects. Defects in such masks can have an order of magnitude in the region of a few nanometers. Repairing such defects necessitates apparatuses which offer a very high spatial resolution for the repair processes.

Suitable apparatuses for this purpose are those that activate local etching or deposition processes on the basis of particle beam-induced processes. For example, EP 1 587 128 B1 discloses such an apparatus. According to this publication, an electron beam from an electron microscope is used to trigger the chemical processes.

In order to be able to carry out such repair processes without errors, what is desirable is symmetrical edge brightness of the viewed structures in image representations (scanning electron microscope image) by use of backscattered electrons. FIG. 6 shows by way of example a surface of a lithography mask 10 imaged in an image 604 (it is noted that FIG. 6 shows only a portion of the image 604). Structures shown there are delimited—as illustrated by way of example for one such structure—by edges 600, 602. As highlighted by the arrow in FIG. 6, the edge 600 has a lower brightness than the edge 602 symmetrical thereto in relation to the axis of symmetry S. In these cases, problems may occur in particular in the course of automated structure recognition in images 604. An additional factor is that in conjunction with asymmetry of the edge brightness, there may be a gradient of the greyscale values over the entire image region. This inhomogeneity may lead to premature or belated termination of the repair process and thus to defects on the lithography mask 10.

### SUMMARY

Therefore, an aspect of the present invention is to provide an improved approach, in particular in order to ensure symmetrical edge brightnesses in viewed structures.

In order to achieve this aspect, a column, in particular for analyzing and/or processing a sample, for example a mask for a lithography apparatus, is proposed. The column comprises:
a particle source configured to emit a particle beam in a first direction onto a sample,
a detector device configured to detect particles moving in a second direction opposite to the first direction, and
a positioning device configured to position the detector device in a plane oriented perpendicular to the first direction.

As a result, the detector device can always be positioned optimally in relation to the optical axis of the beam path (of the particle beam).

In particular, the detector device comprises an opening, through which the particle beam from the particle source is incident on the sample during operation of the column. In embodiments, the opening in the detector device is arranged concentrically with the optical axis of the beam path or of the particle beam. Such an arrangement can easily be attained and maintained with the aid of the positioning device, in particular even for example if geometric changes arise in the column on account of thermal, mechanical or other effects.

Further, the positioning device is, in particular, configured to position the detector device in said plane by adjusting a position of the detector device in said plane. The position of the detector device is, for example, adjusted from a first position to at least one second position, wherein both the first and the at least one second positions are positions in which the detector device is configured (i.e., is capable) to detect the particles moving in the second direction. Moreover, the detector device is, for example, configured to generate at least one image based on the detected particles in each of the first and the at least one second positions.

The detector device is, in particular, configured to detect particles for generating images based on the detected particles. Furthermore, the positioning device is, in particular, configured to position the detector device such that an asymmetrical edge brightness in the generated images can be corrected.

In accordance with one embodiment, positioning the detector device with the aid of the positioning device can take place in situ. That is to say that the positioning takes place in the state in which the detector device has been installed in the column. Preferably, positioning the detector device can take place during operation of the column. That is to say that the detector device is positioned with the aid of the positioning device while the detector device detects particles moving in the second direction. In particular, the detector device can be positioned with the aid of the positioning device while the particle beam is incident through the above-mentioned opening in the detector device.

In these embodiments, the detector device advantageously does not need to be demounted from the column in order to change the position thereof in relation to the optical axis, which reduces maintenance times. Moreover, demounting the detector device from the column is laborious and requires specially trained personnel.

Analyzing and/or processing the sample as mentioned above can take place with the aid of an electron beam and/or ion beam, for example. The particle source can be an electron beam source and/or an ion beam source. In particular, analyzing the sample can comprise metrological measurement of a sample, in particular of imaging structures in the case of a lithography mask. Processing the sample can be in particular removing or adding excess or missing material on the sample in regions with a diameter of a few nanometers.

The detector device can have a detector area, by means of which the incident particles are converted into a light signal. Said light signal can be transported to a photomultiplier. There the light is converted into an electrical signal that can be used for further image processing. In front of the detector area, a potential can be applied which is used to allow only particles having energies above a specific value to be incident on the detector area.

The first and/or second direction(s) can correspond to the vertical direction or can comprise a component in the vertical direction. The plane can be arranged horizontally. The first and second directions are chosen in particular so as to avoid a collision between the particles (in particular electrons) flying in the first direction and those particles (in particular electrons) which fly in the second direction. In particular, for this purpose, the second direction can have an opening angle in relation to the optical axis or vertical direction.

In accordance with one embodiment, the column furthermore comprises an arm, which at the free end thereof comprises the detector device.

As a result, the detector device can be suitably positioned within the column.

In accordance with a further embodiment, the arm is held movably at its other end with the aid of the positioning device.

The detector device is moved by way of the arm being moved.

In accordance with a further embodiment, the column comprises a housing, in which a vacuum prevails and the particle beam moves, wherein the detector device is arranged in the vacuum and is positionable in the plane with the aid of the positioning device, without breaching the vacuum.

The fact that the vacuum is not breached even during the positioning of the detector device affords the advantage that the positioning process can be controlled with the aid of an image which is generated by particles emitted and detected during the positioning process.

In accordance with a further embodiment, the arm extends into the housing from outside through an opening and is sealed with respect to said housing, wherein the positioning device is preferably arranged outside the housing.

As a result, the positioning device is readily accessible.

In accordance with a further embodiment, a ring seal is provided for sealing purposes, said ring seal sliding sealingly over a mating surface of the housing or of the arm.

As a result, the vacuum is maintained in a simple manner while the arm is moving relative to the housing.

Alternative sealing arrangements are described for example in U.S. Pat. Nos. 4,800,100, 5,109,724 and Chatzipetros, J. et. al., “Herstellung von Experimentiereinrichtungen in der Betriebsabteilung Technische Dienste—Mechanische Werkstätten (TD-MW)”, ISSN 0343-7639, October 1986, page 34.

In accordance with a further embodiment, the positioning device is configured to move the arm along a first axis into the opening and out of the latter and also along a second axis perpendicular to the first axis, wherein the first and second axes span the plane.

In accordance with a further embodiment, the positioning device comprises at least one or two adjusting screws configured to act on the arm in order to adjust the latter in the plane.

The adjusting screws can be adjusted or turned, for example, using hexagon keys. In particular, it is provided that the detector device can be positioned with an accuracy of smaller than 10 μm.

In accordance with one embodiment, the detector device is configured for detecting electrons backscattered from the sample.

Alternatively or additionally, the detector device can be configured for detecting so-called secondary electrons. Precisely by virtue of this type of detector devices—as described above—being positionable, a symmetrical edge brightness in image representations can be suitably attained.

In accordance with a further embodiment, the column comprises a plurality of deflection coils for at least double deflection of the particle beam.

In the case of columns with double beam deflection, an asymmetrical edge brightness can be corrected particularly well by positioning the detector device in the plane. Alternatively, the column can also have just single beam deflection and for this purpose, if appropriate, can be provided with just one deflection coil. Preferably, the beam is deflected with the aid of the one or more coils before it is incident on the sample.

In a generalized manner, the column can be configured to the effect that the relative position of the particle beam and of the detector device is settable or is set optionally by use of (1) energizing one or more deflection coils and (2) positioning the detector device in the plane. In embodiments, steps (1) and (2) can take place in a manner staggered over time or at the same time.

In accordance with a further embodiment, the detector device comprises a small tube, through which the particle beam is guided.

In particular, the small tube forms the above-mentioned opening of the detector device.

In accordance with a further embodiment, the column is designed as an electron beam column or an ion beam column.

In accordance with a further aspect, a processing arrangement for analyzing and/or processing a sample, in particular a scanning electron microscope, is provided, comprising the column described above.

The processing arrangement may, for example, comprise a gas provision unit for supplying one or more process gases at a surface of the sample (e.g., into a region of a focal point of the electron beam).

Having the gas provision unit, electron beam induced processing (EBIP) of the sample (e.g., lithography mask) can be carried out. This encompasses, for example, depositing material on and/or etching material of the sample (e.g., the sample surface).

The processing arrangement may, for example, comprise a vacuum housing (first vacuum housing) for generating a vacuum with a first pressure inside the first vacuum housing. The column of the processing arrangement may, for example, comprise a second vacuum housing arranged inside the first vacuum housing. The second vacuum housing is, in particular, configured for generating a vacuum with a second pressure inside the second vacuum housing. The second pressure is, for example, larger than the first pressure.

Hence, inside the first vacuum housing there is a first region (first volume) having the first pressure. The first region is inside the first vacuum housing but outside of the second vacuum housing. Further, inside the first vacuum housing there is a second region (second volume) having the second pressure. The second region is defined by the second vacuum housing arranged inside the first vacuum housing. In other words, the second region is inside the first vacuum housing and inside the second vacuum housing.

The detector device is, in particular, arranged in the second vacuum housing in the vacuum with the second pressure (i.e., in the second region). Further, a sample stage for supporting the sample is, for example, arranged inside the first vacuum housing (but not inside the second vacuum housing) in the vacuum with the first pressure (i.e., in the first region).

Having the second pressure (which is higher than the first pressure) inside the second vacuum housing of the column prevents that process gases supplied to a surface of the sample (e.g., into a region of a focal point of the electron beam) enter the interior of the second vacuum housing. Thus, damages caused by process gases of components of the column arranged inside the second vacuum housing—including the detector device—can be prevented.

The first pressure has, for example, a value in the range of 10⁻⁷ to 10⁻¹⁰ mbar and/or 10⁻⁷ to 10⁻⁹ mbar and/or 10⁻⁷ to 10⁻⁸ mbar and/or 10⁻⁸ to 10⁻⁹ mbar and/or 10⁻⁸ to 10⁻¹⁰ mbar.

The second pressure has, for example, a value in the range of 10⁻⁵ to 10⁻⁷ mbar and/or 10⁻⁵ to 10⁻⁶ mbar.

In accordance with a further aspect, a method for analyzing and/or processing a sample, in particular a mask for a lithography apparatus, is provided. The method comprises:
a) emitting a particle beam in a first direction onto a sample;
b) detecting, with the aid of a detector device, particles moving in a second direction opposite to the first direction; and
c) positioning the detector device in a plane oriented perpendicular to the first direction.

In accordance with one embodiment, the positioning in accordance with step c) takes place in situ.

In accordance with a further embodiment, during step c), the detector device is situated in the vacuum. A positioning device for positioning the detector device is preferably situated outside the vacuum. Preferably, positioning the detector device in accordance with step c) takes place without breaching the vacuum.

In the present case, processing the sample can comprise in particular depositing or etching on the surface of the sample. One or more process gases are preferably used for the depositing or etching.

Appropriate process gases suitable for depositing material or for growing elevated structures are, in particular, alkyl compounds of main group elements, metals or transition elements. Examples thereof are (cyclopentadienyl)trimethylplatinum CpPtMe₃ (Me=CH₄), (methylcyclopentadienyl)trimethylplatinum MeCpPtMe₃, tetramethyltin SnMe₄, trimethylgallium GaMe₃, ferrocene Cp₂Fe, bis-arylchromium Ar₂Cr, and/or carbonyl compounds of main group elements, metals or transition elements, such as, for example, chromium hexacarbonyl Cr(CO)₆, molybdenum hexacarbonyl Mo(CO)₆, tungsten hexacarbonyl W(CO)₆, dicobalt octacarbonyl Co₂(CO)₈, triruthenium dodecacarbonyl Ru₃(CO)₁₂, iron pentacarbonyl Fe(CO)₅, and/or alkoxide compounds of main group elements, metals or transition elements, such as, for example, tetraethyl orthosilicate Si(OC₂H₅)₄, tetraisopropoxytitanium Ti(OC₃H₇)₄, and/or halide compounds of main group elements, metals or transition elements, such as, for example, tungsten hexafluoride WF₆, tungsten hexachloride WCl₆, titanium tetrachloride TiCl₄, boron trifluoride BF₃, silicon tetrachloride SiCl₄, and/or complexes comprising main group elements, metals or transition elements, such as, for example, copper bis(hexafluoroacetylacetonate) Cu(C₅F₆HO₂)₂, dimethylgold trifluoroacetylacetonate Me₂Au(C₅F₃H₄O₂), and/or organic compounds such as carbon monoxide CO, carbon dioxide CO₂, aliphatic and/or aromatic hydrocarbons, and the like. Appropriate process gases suitable for etching material are, for example: xenon difluoride XeF₂, xenon dichloride XeCl₂, xenon tetrachloride XeCl₄, water vapor H₂O, heavy water D₂O, oxygen O₂, ozone O₃, ammonia NH₃, nitrosyl chloride NOCl and/or one of the following halide compounds: XNO, XONO₂, X₂O, XO₂, X₂O₂, X₂O₄, X₂O₆, where X is a halide. Further process gases for etching material are specified in the present applicant's US patent application having the number Ser. No. 13/103,281, issued as U.S. Pat. No. 9,721,754 on Aug. 1, 2017.

The embodiment or features described above for the column are correspondingly applicable to the processing arrangement and the method, and vice versa.

“A(n); one” in the present case should not necessarily be understood as restrictive to exactly one element. Rather, a plurality of elements, such as two, three or more, can also be provided. Nor should any other numeral used here be understood to the effect that there is a restriction to exactly the stated number of elements. Rather, unless indicated otherwise, numerical deviations upwards and downwards are possible. Furthermore, the method steps described can also be performed in a different sequence, for example first step c), then step a), unless indicated otherwise.

Further possible implementations of the invention also encompass not explicitly mentioned combinations of features or embodiments that are described above or hereinafter with respect to the exemplary embodiments. In this case, a person skilled in the art will also add individual aspects as improvements or supplementations to the respective basic form of the invention.

Further advantageous configurations and aspects of the invention are the subject matter of the dependent claims and also of the exemplary embodiments of the invention that are described below. The invention is explained in greater detail hereinafter on the basis of preferred embodiments with reference to the accompanying figures.

### DESCRIPTION OF DRAWINGS

FIG. 1 shows a schematic view of a processing arrangement for checking and/or repairing a lithography mask;

FIG. 2 shows an electron beam column of the processing arrangement from FIG. 1;

FIG. 3 shows an arrangement of scanner coils from the electron beam column from FIG. 2;

FIG. 4 shows, as viewed in a horizontal direction, a detector device of the electron beam column from FIG. 2 in accordance with one embodiment;

FIG. 4A shows a detail of a detector device together with arm in a plan view from FIG. 4;

FIG. 5 shows a flow diagram of a method in accordance with one embodiment; and

FIG. 6 shows a structured surface of a lithography mask in a plan view.

### DETAILED DESCRIPTION

Elements that are identical or functionally identical have been provided with the same reference signs in the figures, to the extent that one is specified. It should also be noted that the representative figures are not necessarily true to scale.

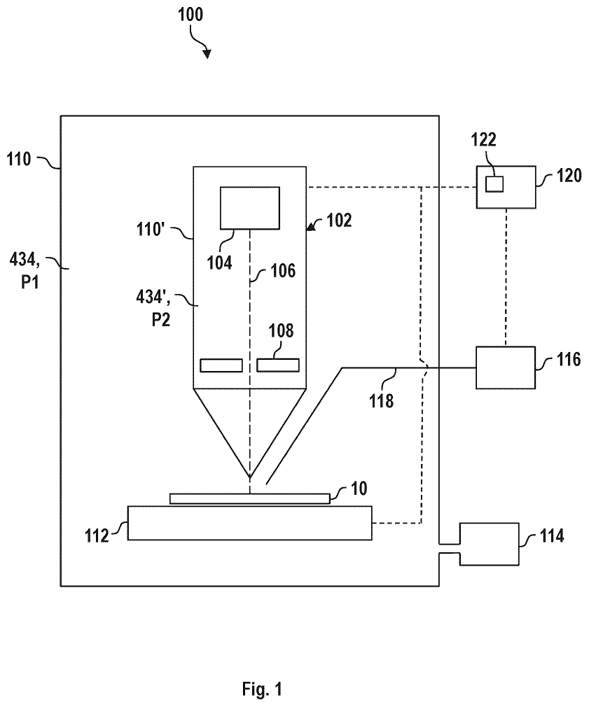

FIG. 1 schematically shows one exemplary embodiment of a processing arrangement 100 embodied, for example, in the form of a scanning electron microscope. The processing arrangement 100 serves to check and/or to repair a sample, for example a lithography mask 10. The lithography mask 10 is intended, for example, for use in an EUV or DUV lithography apparatus (not shown).

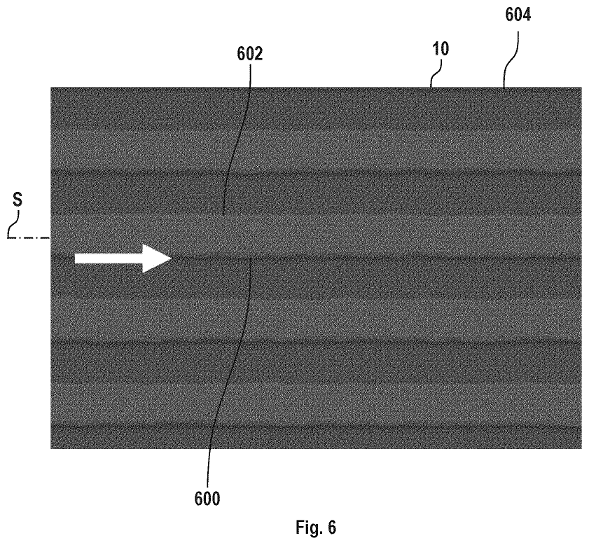

The processing arrangement 100 comprises an electron beam column 102. The latter comprises an electron source 104, which generates an electron beam 106. The electron beam 106 is incident on the lithography mask 10. Backscattered electrons and/or secondary electrons are detected by a detector arrangement 108 of the electron beam column 102. It is thus possible to create a high-resolution image 604 (FIG. 6) of the lithography mask 10 (electron beam microscope).

The processing arrangement 100 comprises a vacuum housing 110 (first vacuum housing 110). The electron beam column 102 is arranged in the first vacuum housing 110. The same applies to the lithography mask 10, which is arranged on a sample stage 112 beneath the electron beam column 102. The vacuum 434 within the first vacuum housing 110 is generated with the aid of a vacuum pump 114. For example, there is a residual gas pressure P1 of 10⁻⁷ mbar to 10⁻⁸ mbar within the first vacuum housing 110.

The electron beam column 102 may comprise a further vacuum housing 110′ (second vacuum housing 110′), as shown in FIG. 1. The second vacuum housing 110′ of the electron beam column 102 is, for example, arranged inside the first vacuum housing 110 of the processing arrangement 100. A pressure inside the second vacuum housing 110′ is denoted with the reference sign P2.

The vacuum 434′ within the second vacuum housing 110′ is generated with the aid of a second vacuum pump (not shown). For example, a residual gas pressure P2 within the second vacuum housing 110′ is 10⁻⁵ mbar to 10⁻⁶ mbar.

The electron beam column 102 can carry out electron beam induced processing (EBIP) processes in interaction with process gases supplied, which are supplied for example by a gas provision unit 116 from outside via a gas line 118 into the region of a focal point of the electron beam 106. This encompasses in particular depositing material on or etching material of the lithography mask 10. In particular, a control computer 120 of the processing arrangement 100 is configured to control the electron beam column 102, the sample stage 112 and the gas provision unit 116 in a manner suitable for this purpose. In particular, a computer program 122 is stored on the control computer 120, and controls the processing arrangement 100 to perform a predetermined method.

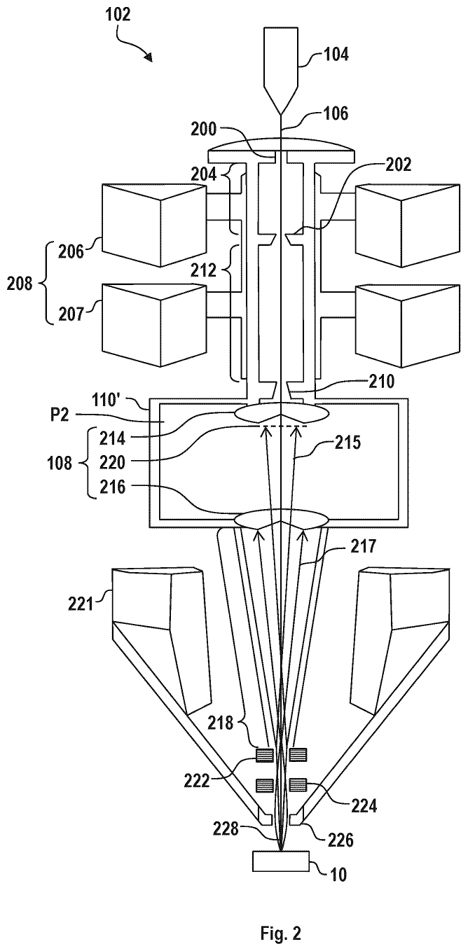

FIG. 2 shows the electron beam column 102 from FIG. 1 in greater detail. By comparison with FIG. 1, FIG. 2 furthermore shows that the electron beam column 102 comprises an anode aperture 200 disposed downstream of the electron source 104 in the beam path. The anode aperture 200 is followed in the beam path by an aperture stop 202 with one or more openings. A first condenser 206 of a double condenser 208 is assigned to the beam path section 204 between the anode aperture 200 and the aperture stop 202. The aperture stop 202 is followed by a further stop 210. The beam path section 212 between the aperture stop 202 and the further stop 210 (which can, for instance, be a pressure stage stop) is surrounded by a second condenser 207 of the double condenser 208. The stop 210 is followed in the beam path by the detector arrangement 108 already mentioned in connection with FIG. 1.

In detail, the detector arrangement 108 can comprise an ESB detector 214 (ESB: “Energy Selective Backscatter”) and/or an SE detector 216 (SE: “Secondary Electron”). The ESB detector 214 is configured to detect backscattered electrons 215 of the electron beam 106. For this purpose, the ESB detector 214 detects electrons 215 having an energy starting from 200 eV, for example. The ESB detector 214 can comprise a filter grating 220 at its underside. The SE detector 216 is configured to detect secondary electrons 217. These are electrons 217 having an energy of up to 50 eV, for example, which are ejected from the lithography mask 10 by use of the electron beam 106.

The further beam path section 218 that follows the detector arrangement 108 is surrounded by a magnetic lens 221. The electron beam 106 is finally guided out of the electron beam column 102 onto the lithography mask 10 (or some other sample) via in particular two or more scanner coils 222, 224, which are responsible for the scanning of the lithography mask 10, and preferably an electrostatic lens 226.

The above-described set-up of the electron beam column 102 should be understood to be purely by way of example and can be embodied differently in various regions. For example, a single condenser can be provided instead of the double condenser 208. Alternatively, an ion beam column can be provided instead of the electron beam column 102.

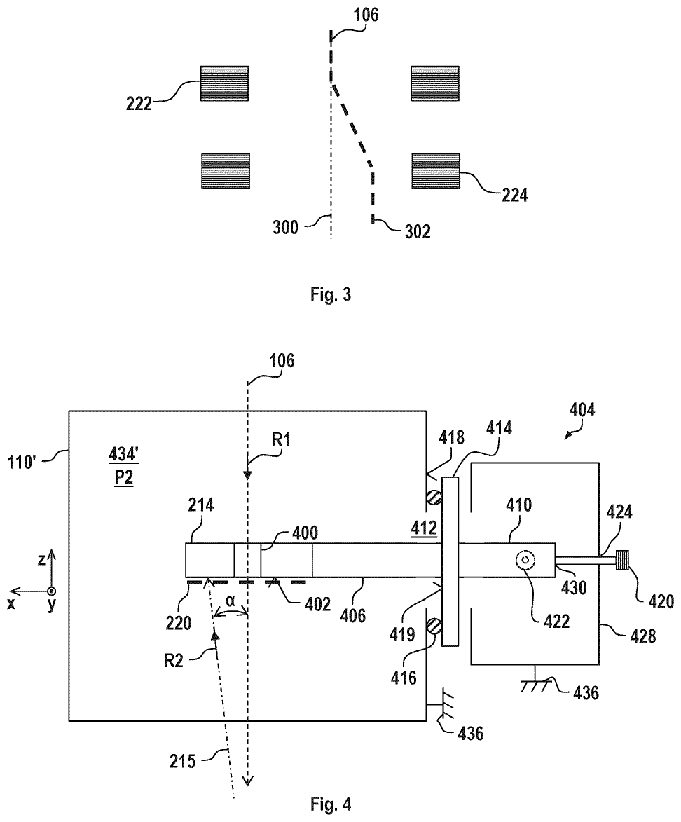

FIG. 3 shows the scanner coils 222, 224 already described in connection with FIG. 2, which are arranged successively in the beam path. The scanner coils 222, 224 can each be of ring-shaped design, and FIG. 3 shows a sectional view perpendicular to the ring plane. The illustration in FIG. 3 may also be referred to as a vertical sectional view from FIG. 2.

Furthermore, an optical axis 300 is shown in FIG. 3. The undeflected electron beam 106 moves along said optical axis 300 from the electron source 104 (see FIGS. 1 and 2) towards the lithography mask 10. With the aid of the scanner coils 222, 224, it is possible to cause a double deflection of the electron beam 106 proceeding from the optical axis 300, such that the doubly deflected electron beam 302, after passing through the last of the two scanner coils 224, again flies parallel to the optical axis 300. An imaging quality that can be achieved with the electron beam column 102 can be improved with the aid of the double beam deflection.

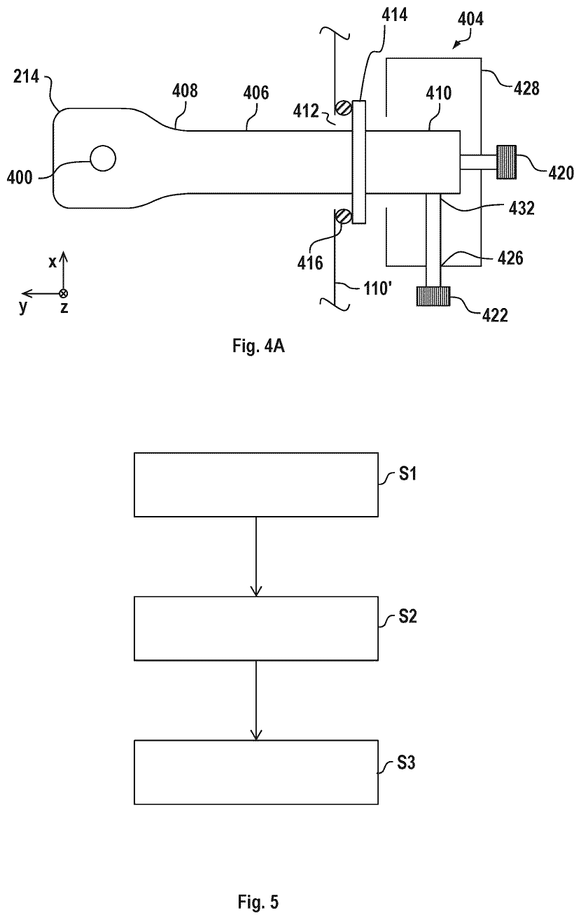

Precisely in embodiments with double beam deflection, a positionable detector device, as shown in FIG. 4, has proved to be particularly advantageous in order to attain a symmetrical edge brightness of the edges 600, 602 (see FIG. 6) in the image representation 604. The purely exemplary set-up in accordance with FIG. 4 is explained in greater detail below.

The detector device shown in FIG. 4 is the ESB detector 214, for example, although it could be the SE detector 216 or some other detector in other embodiments.

The ESB detector 214 is arranged for example in the second vacuum housing 110′ of the electron beam column 102. The ESB detector 214 can comprise an opening, which in the present case is designed, for example, in the form of a small tube 400. The electron beam 106 passes through the small tube 400 in the vertical direction R1 and is incident on the sample 10. As already explained in connection with FIG. 2, the electrons 215 backscattered from the sample 10 are detected by the ESB detector 214. For this purpose, the ESB detector 214 can optionally comprise a filter grating 220 at its underside. While the electrons in the electron beam 106 move downwards in the vertical direction R1, the backscattered electrons 215 move in the opposite direction R2 thereto (i.e., at least with a component pointing in the opposite direction R2). The backscattered electrons 215 typically have an opening angle α in relation to the electron beam 106 or the optical axis 300 (see FIG. 3). This has the effect that the backscattered electrons 215 do not fly back through the small tube 400, but rather onto a detector area 402 at the underside of the ESB detector 214.

The ESB detector 214 is provided such that it is positionable in the xy-plane with the aid of a positioning device 404. In the present case, the xy-plane corresponds to the horizontal plane, for example. The z-direction perpendicular thereto corresponds to the vertical. The detector area 402 that detects the backscattered electrons 215 likewise extends in the xy-plane, for example. The particle beam 106 moves downwards (direction R1) in the z-direction. The backscattered electrons 215 fly upwards (direction R2) in the z-direction.

FIG. 4A shows as a detail a plan view from FIG. 4. FIGS. 4 and 4A reveal that the detector 214 is mounted on one end 408 of an arm 406. The arm 406 is held movably at its other end 410. The arm 406 projects into the second vacuum housing 110′ via an opening 412 (in particular a hole). By way of example, a flange 414 or some other suitable geometry allowing the arm 406 to be sealed vis-à-vis the second vacuum housing 110′ can be formed on the arm 406. In accordance with the exemplary variant shown here, the flange 414 bears against a mating surface 418 (exterior side) of the housing 110′ in a vacuum-type manner by way of a ring seal 416. Either the ring seal 416 can slide sealingly over the mating surface 418 or a mating surface 419 on the flange 414 (associated with the arm 406) can slide sealingly over the seal 416 in the yz-plane in order to ensure the vacuum-tightness when the arm 406 and hence the flange 414 are positioned in the xy-plane by use of the positioning device 404.

By way of example, the positioning device 404 can comprise two or more adjusting screws 420, 422. The screws 420, 422 can be screwed through openings 424, 426 (FIGS. 4 and 4A) in a housing 428 (or some other mount). By screwing the screws 420, 422 in and out, for example with the aid of a hexagon key, the screws 420, 422 can exert a corresponding tension or pressure on the end 410 of the arm 406 with the aid of their ends 430, 432. As a result, the arm 406 and hence the ESB detector 214 together with filter grating 220 are moved in the xy-plane. The second vacuum housing 110′ and the housing 428 are provided so as each to be stationary with respect to one another and are mounted on the base 436 for this purpose.

This movement of the ESB detector 214 together with filter grating 220 can take place in situ, in particular, that is to say with the ESB detector 214 together with filter grating 220 having been installed in the electron beam column 102, as shown in FIGS. 4 and 4A. In particular, in this case the ESB detector 214 is arranged in the vacuum 434′. That is to say that the vacuum 434′ is not breached in order to adjust the position of the ESB detector 214. The position can also be adjusted in particular when (i.e., at the same time) the electron beam 106 is moving through the small tube 400.

The inventors have discovered that an asymmetrical edge brightness (see FIG. 6) in the case of images 604 recorded by the ESB detector 214 can be counteracted particularly well by means of such an adjustment of the ESB detector 214. In this case, the current scanning electron microscope image 604 is viewed in situ and at the same time the ESB detector 214 is displaced until the edge brightness is symmetrical.

FIG. 5 schematically shows a flow diagram of a method for analyzing and/or processing a sample, in particular a mask 10 for a lithography apparatus, in accordance with one embodiment.

In step S1, a particle beam 106 (see FIGS. 1 to 4) is emitted in a first direction R1 onto a sample 10.

In a step S2, particles 215, 217 moving in a second direction R2 opposite to the first direction R1 are detected with the aid of the detector device 214, 216.

In a step S3, the detector device 214, 216 is positioned in a plane x, y oriented perpendicular to the first direction R1. The positioning in step S3 can take place in situ. In particular, in this case, the detector device 214, 216 is situated in the vacuum 434′, while a positioning device 404 for positioning the detector device 214, 216 is situated outside the vacuum 434′.

The processing arrangement 100 can be designed in particular in the form of an electron beam microscope, comprising the column 102 described above. Such a processing arrangement 100 is configured in particular for analyzing a sample 10. Additionally or alternatively, the processing arrangement 100 can be designed for processing the sample 10. The processing can comprise in particular etching or depositing using one or more process gases. For this purpose, the processing arrangement 100 can comprise, for example, one or more supply devices 116, 118 for one or more process gases.

### Although the present invention has been described on the basis of exemplary embodiments, it can be modified in various ways.

### LIST OF REFERENCE SIGNS

10 Lithography mask
100 Processing arrangement
102 Electron beam column
104 Electron source
106 Electron beam
108 Detector arrangement
110, 110′ Vacuum housing
112 Sample stage
114 Vacuum pump
116 Gas provision unit
118 Gas line
120 Control computer
122 Computer program
200 Anode stop
202 Aperture stop
204 Beam path section
206 Condenser
207 Condenser
208 Double condenser
210 Stop
212 Beam path section
214 ESB detector
215 Backscattered electrons
216 SE detector
220 Filter grating
221 Magnetic lens
222 Scanner coil
224 Scanner coil
226 Electrostatic lens
300 Optical axis
302 Deflected particle beam
400 Small tube
402 Detector area
404 Positioning device
406 Arm
408 End
410 End
412 Opening
414 Flange
418 Mating surface
419 Mating surface
420 Screw
422 Screw
424 Opening
426 Opening
428 Housing
430 End
432 End
434, 434′ Vacuum
436 Base
600 Edge
602 Edge
604 Image
P1 First pressure
P2 Second pressure
R1 First direction
R2 Second direction
S Axis of symmetry
S1-S3 Method steps
x, y, z Axes

What is claimed is:

1. A column for analyzing and/or processing a sample, for example a mask for a lithography apparatus, comprising:
a particle source configured to emit a particle beam in a first direction onto the sample,
a detector device configured to detect particles moving in a second direction opposite to the first direction for generating images, and
a positioning device configured to position the detector device in a plane oriented perpendicular to the first direction such that an asymmetrical edge brightness in the generated images is corrected.

2. The column of claim 1, wherein
the positioning device is configured to adjust a position of the detector device from a first position to at least one second position, and
the detector device is configured to detect particles in both the first and the at least one second positions, and/or
the detector device is configured to generate at least one image based on the detected particles in each of the first and the at least one second positions.

3. The column of claim 1, wherein the detector device is configured to detect particles for generating images, and the positioning device is configured to position the detector device such that an asymmetrical edge brightness in the generated images is corrected.

4. The column of claim 1, furthermore comprising an arm, which at one end thereof comprises the detector device.

5. The column of claim 4, wherein the arm is held movably at its other end with the aid of the positioning device.

6. The column of claim 1, furthermore comprising a housing, in which a vacuum prevails and the particle beam moves, wherein the detector device is arranged in the vacuum and is positionable in the plane with the aid of the positioning device, without breaching the vacuum.

7. The column of claim 4, wherein the arm extends into the housing from outside through an opening and is sealed with respect to said housing, wherein the positioning device is preferably arranged outside the housing.

8. The column of claim 7, wherein a ring seal is provided for sealing purposes, said ring seal sliding sealingly over a mating surface of the housing or of the arm.

9. The column of claim 7, wherein the positioning device is configured to move the arm along a first axis into the opening and out of the latter and also along a second axis perpendicular to the first axis, wherein the first and second axes span the plane.

10. The column of claim 4, wherein the positioning device comprises at least one or two adjusting screws configured to act on the arm in order to adjust the latter in the plane.

11. The column of claim 1, wherein the detector device is configured for detecting electrons backscattered from the sample.

12. The column of claim 1, comprising a plurality of deflection coils for at least double deflection of the particle beam.

13. The column of claim 1, which is designed as an electron beam column or an ion beam column.

14. A processing arrangement for analyzing and/or processing a sample, in particular a mask for a lithography apparatus, comprising a column according to claim 1.

15. The processing arrangement of claim 14 comprising a column according to claim 6, wherein
the processing arrangement comprises a first housing in which a vacuum with a first pressure prevails,
the housing of the column, in which a vacuum prevails and in which the detector device is arranged, is a second housing with a vacuum with a second pressure,
the second housing is accommodated in the first housing,
the second pressure is higher than the first pressure, and
a sample stage for supporting the sample is accommodated in the first housing in the vacuum with the first pressure.

16. A method for analyzing and/or processing a sample, in particular a mask for a lithography apparatus, comprising:
a) emitting a particle beam in a first direction onto a sample;
b) detecting, with the aid of a detector device, particles moving in a second direction opposite to the first direction for generating images; and
c) positioning the detector device in a plane oriented perpendicular to the first direction such that an asymmetrical edge brightness in the generated images is corrected.

17. The method of claim 16, wherein the positioning in accordance with step c) takes place in situ.

18. The method of claim 16, wherein, during step c), the detector device is situated in the vacuum, wherein positioning the detector device in accordance with step c) preferably takes place without breaching the vacuum.

19. The method of claim 17, wherein, during step c), the detector device is situated in the vacuum, wherein positioning the detector device in accordance with step c) takes place without breaching the vacuum.

20. The column of claim 2, wherein the detector device is configured to detect particles for generating images, and the positioning device is configured to position the detector device such that an asymmetrical edge brightness in the generated images is corrected.
